(19) United States
(12) Patent Application Publication
(10) Pub. No.: US 2009/0294985 A1
(43) Pub. Date: Dec. 3, 2009

(54) THIN CHIP SCALE SEMICONDUCTOR PACKAGE

(76) Inventor: Jocel P. Gomez, Lapu-Lapu City (PH)

Correspondence Address: KENNETH E. HORTON;KIRTON & MCCONKLE, 60 EAST SOUTH TEMPLE, SUITE 1800, SALTLAKE CITY, UT, 84111, US

(21) Appl. No.: 12/128,867

(22) Filed: May 29, 2008

(51) Int. Cl. H01L 23/48; H01L 21/44

(52) U.S. Cl. 257/774; 438/667; 257/E23.01; 257/E21.476

(57) ABSTRACT

Chip scale semiconductor packages and methods for making and using such semiconductor packages are described. The chip scale packages include multiple terminals that are each disposed on a die back surface that is located opposite to an active area of a semiconductor substrate in the package. The active area can be electrically connected to a plurality of terminals by using traces that may be electrically isolated from the die substrate. In some designs, the terminals can comprise a gate terminal that electrically connected with a gate region of the active area, a source terminal electrically connected with a source region of the active area, and a drain terminal may electrically connected with the die substrate. Other embodiments are also described.

### FIELD

This application relates generally to semiconductor devices and methods for making such devices. Specifically, this application describes chip scale semiconductor packages that include multiple terminals that are each disposed on a die back surface that is located opposite to an active area of the semiconductor package.

### BACKGROUND

Semiconductor packages are well known in the art. Often, these packages may include one or more semiconductor devices, such as an integrated circuit (“IC”) die or chip, which may be connected to a die pad that is centrally formed in a lead frame. In some cases, bond wires or solder bumps electrically connect the IC die to a series of terminals that serve as an electrical connection to an external device, such as a printed circuit board (“PCB”). An encapsulating material can be used to cover the IC die, the terminals, and/or other components of the semiconductor device to form the exterior of the semiconductor package. A portion of the terminals and possibly a portion of the die pad may be externally exposed from the encapsulating material. In this manner, the die is protected from environmental hazards-such as moisture, contaminants, corrosion, and mechanical shock-while being electrically and mechanically connected to an intended device that is external to the semiconductor package.

After it has been formed, the semiconductor package is often used in an ever growing variety of electronic devices, such as disk drives, USB controllers, portable computer devices, cellular phones, and so forth. Depending on the die and the electronic application, the semiconductor package may be highly miniaturized and may need to be as small as possible.

In semiconductor packages that are designed for use in small and condensed electronic devices, the terminals that connect the packages to the electronic devices are located on an active surface of the IC die. As a result, the active area of such packages is reduced, along with the amount of circuitry that can be used. Moreover, where the terminals are located on the active surface, the active surface may be damaged by mechanical stresses between the terminals and the electronic device to which they are connected.

Additionally, some semiconductor packages that are designed for use in condensed electronic devices comprise solder ball terminals. The solder ball terminals tend to increase the thickness of the semiconductor packages and thereby reduce the number of applications in which the packages can be used. Additionally, solder ball terminals are often lost or detached during handing and reeling. And solder ball terminals are often deformed by conventional assembly testing processes. Thus, semiconductor packages comprising solder ball terminals may be readily damaged.

### SUMMARY

This application describes chip scale semiconductor packages and methods for making and using such semiconductor packages. The chip scale packages include multiple terminals that are each disposed on a die back surface that is located opposite to an active area of a semiconductor substrate in the package. The active area can be electrically connected to a plurality of terminals by using traces that may be electrically isolated from the die substrate. In some designs, the terminals can comprise a gate terminal that electrically connected with a gate region of the active area, a source terminal electrically connected with a source region of the active area, and a drain terminal may electrically connected with the die substrate.

### BRIEF DESCRIPTION OF THE DRAWINGS

The following description can be better understood in light of the Figures, in which:

FIG. 1 depicts a cutaway view of some embodiments of a semiconductor package;

FIGS. 2(a)-3(b) depicts some embodiments of a semiconductor package;

FIGS. 4(a)-4(d) depicts views of some embodiments of a semiconductor package;

FIGS. 5(a)-5(l) depicts some embodiments of a method for making a semiconductor package;

FIGS. 6(a)-6(e) depicts differing views of some embodiments of a semiconductor package after assembly;

FIG. 7 depicts a cutaway view of some embodiments of a semiconductor package;

FIGS. 8(a)-8(b) depict differing views of some embodiments of a semiconductor package; and

FIGS. 9(a)-9(e) show different views of some embodiments of a semiconductor package after assembly.

The Figures illustrate specific aspects of chip scale semiconductor packages and methods for making and using such semiconductor packages. Together with the following description, the Figures demonstrate and explain the principles of the methods and structures described herein. In the drawings, the thickness of layers and regions are exaggerated for clarity. It will also be understood that when a layer, component, or substrate is referred to as being “on” another layer, component, or substrate, it can be directly on the other layer, component, or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the semiconductor packages and methods for making and using such packages can be implemented and used without employing these specific details. For example, while the description focuses on chip scale semiconductor packages, it may be modified to be used in other types of semiconductor packages, such as adding solder bumps on the terminal pads or attaching with metal studs on terminal pads (e.g. Cu stud). And while the description focuses on wafer level chip scale packages, it may be modified to be used in other types of chip scale packages, including flex circuit interposer type, rigid substrate interposer type.

The Figures illustrate semiconductor packages in which the terminals are disposed on a die surface that is opposite to an active area of the package, and methods for making and using such packages. In some embodiments, the semiconductor package comprises a chip scale package (“CSP”), such as a flexible circuit interposer CSP, a rigid substrate interposer CSP, or a wafer level package. In some embodiments, the semiconductor package comprises a wafer level package.

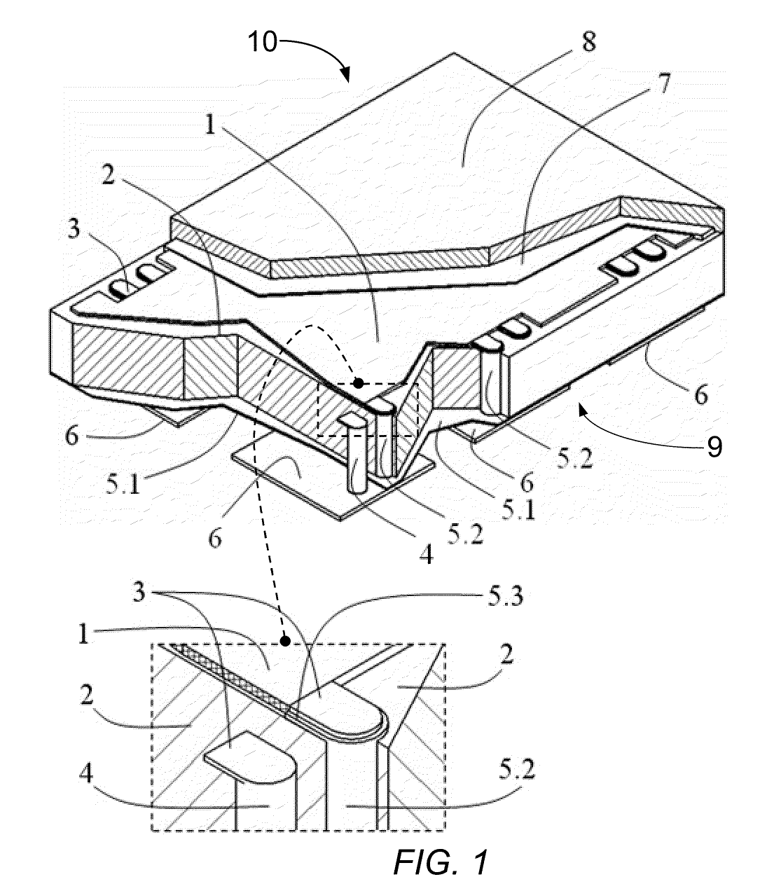

FIG. 1 shows a cutaway view of some embodiments of a semiconductor package 10. FIG. 1 shows the package 10 may comprise a device active area 1, a semiconductor substrate 2, a trace 3, a filled via 4, an isolation layer (e.g., a bottom isolation layer 5.1, a via isolation layer 5.2, and/or a trace isolation layer 5.3), a terminal 6, and/or a protective material (e.g., polyimide 7 and covering material 8). The semiconductor package may also comprise any other known component, such as an interposer and or leadframe based Cupper terminal.

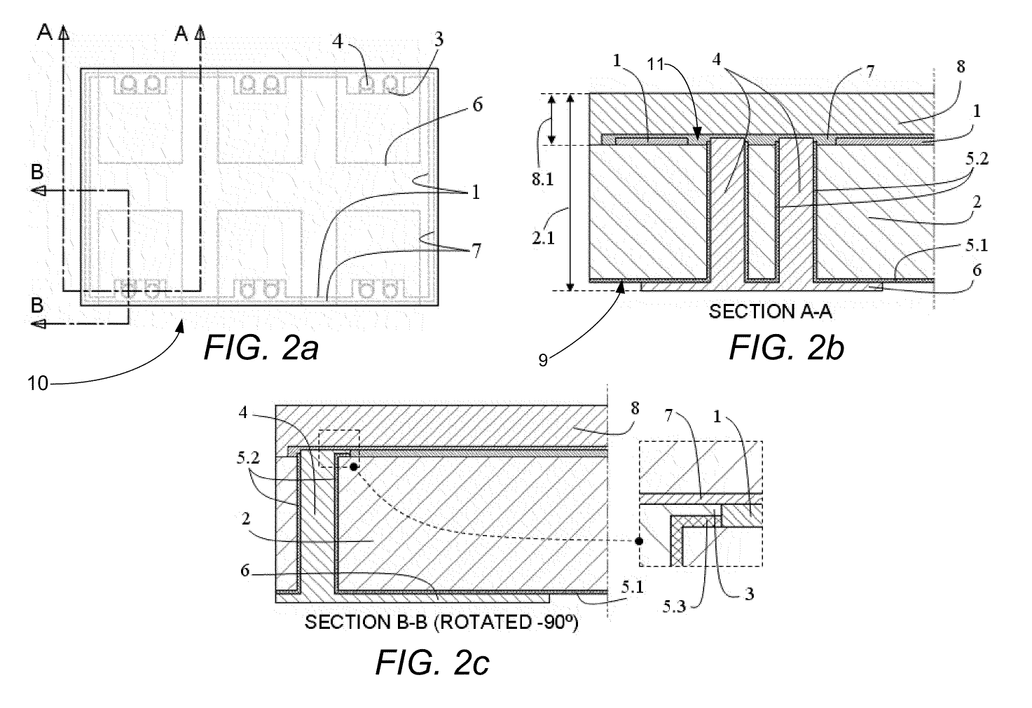

FIG. 2b, which is a side cutaway view of FIG. 2a along line A-A, shows that the semiconductor package 10 may comprise an active area 1. The active area can be any known active region in a semiconductor device. In some embodiments, the active regions comprise discrete power devices, including one or more transistors (such as metal-oxide-semiconductor field-effect transistors (“MOSFET”) devices or insulated gate bipolar transistors), diodes, thyristors, capacitors, gate drivers, controller ICs, etc.

As shown in FIG. 2b, the active area 1 can be located on a semiconductor substrate 2. The semiconductor substrate may comprise any substrate suitable for use in a semiconductor device, including silicon, gallium arsenide, gallium nitride, or germanium. In some embodiments, the substrate 2 comprises or undoped silicon. The substrate 2 comprises a die back surface 9 that is opposite to a die front surface 9 on which the active area 1 is disposed.

The components of the active area 1 may be electrically and/or mechanically connected to other components of the package 10 (including the terminals 6) through any appropriate method or technique known in the art, including copper deposition of traces, vias and insulator deposition. By way of illustration, FIG. 2c shows some embodiments where a trace 3 electrically connects one or more components of the active area 1 with a filled via 4 that extends through the substrate 2 to connect with a terminal 6 on the die back surface 9.

The trace may have any feature that allows it to electrically connect the active area with the filled via. Thus, the trace can be any shape or size known in the art. Additionally, the trace can be made of any known conductive material, including metals or metal alloys of copper, gold, silver, nickel, or any electrically conductive metallic material.

The filled via can have any characteristic that allows it to electrically connect the trace on the front surface with a terminal on the back surface. Thus, the filled via can be any suitable shape or size known in the art. In some embodiments, diameter of the filled via can range from about 5 to 50 μm depending on the based substrate 2 thickness. And the trace can comprise any known conductive material, including metals or metal alloys of copper, gold, silver, nickel, or any electrically conductive metallic material.

All of the terminals 6 are electrically connected to a filled via. In some embodiments, the terminals may be electrically connected to any desired number of filled vias. For example, a single terminal can be connected to a single filled via that extends between the back surface and the front surface. In another example, FIG. 2b shows that terminal 6 can be attached to 2 filled vias 4. In still another example, a terminal can be attached to 3, 4, 5, or more filled vias. Indeed, in some embodiments, connecting multiple filled vias to a single terminal may provide a more reliable interconnection.

The semiconductor package 10 also comprises terminals 6 on the back surface. The package may comprise any type of terminal that electrically connects the package to an external device, such as a PCB. For instance, the semiconductor package may comprise pad terminals or solder ball terminals. In some embodiments, as illustrated in FIGS. 1 and 2a, the semiconductor package may comprise pad terminals on the opposite side of the active area 1 because they may serve to reduce package thickness and be less likely to be damaged or displaced than solder ball terminals directly attached to the active area surface.

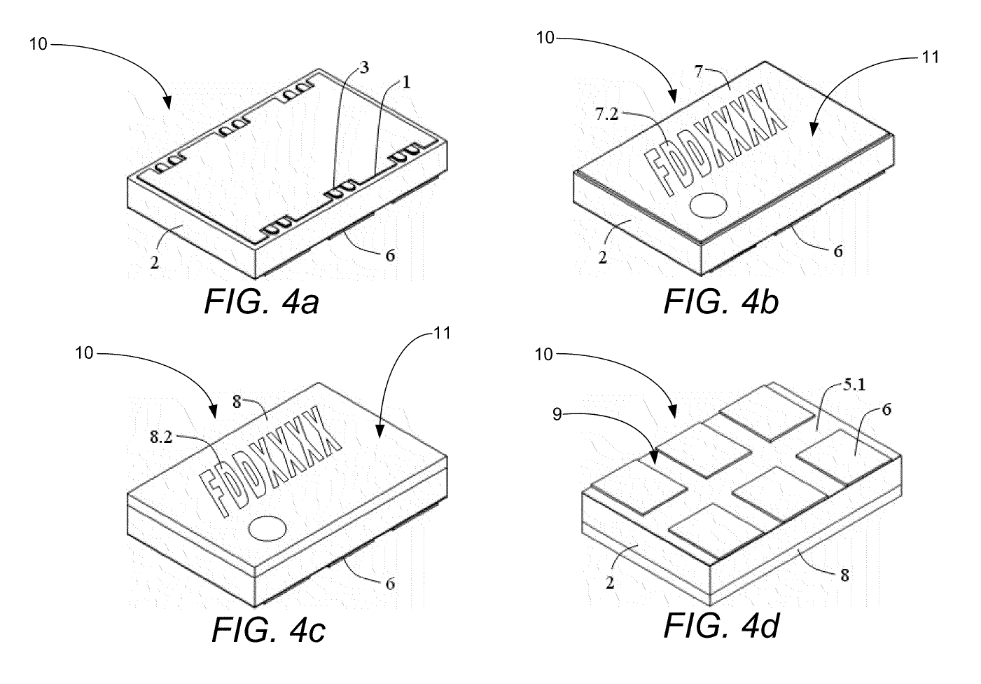

The pad terminals may have any characteristic that allows them to electrically connect one or more filled vias (and therefore the active area) with an external device. Thus, the pad terminals are made of any known conductive material that provides a suitable electrical and mechanical interface. The pad terminals may be any known shape or size, including substantially circular, square, or rectangular as shown in FIG. 4d.

The semiconductor package 10 may comprise any number of terminals that provides a reliable electrical and mechanical connection between the package and the external device. In some embodiments, the semiconductor package 10 can comprise 3, 4, or more terminals (e.g., 6, 8, or 10). FIG. 4d shows some embodiments where the package 10 comprises six terminals.

In some embodiments, the electrical connection from the active area to the terminals can be isolated from the substrate. For example, the semiconductor package 10 can comprise an isolation layer disposed between the substrate and the components that are electrically connected to the active area. For instance, FIG. 2c shows some embodiments where the substrate 2 is electrically isolated from the terminal 6 and filled vias 4 by isolation layers 5.1 and 5.2, respectively. Similarly, FIG. 2c shows the substrate 2 can be electrically isolated from the trace 3 by an isolation layer 5.3. The isolation layer (e.g., layers 5.1, 5.2, and/or 5.3) may comprise any insulating material suitable for use in the semiconductor package. For example, the isolation layer can comprise silicon oxide, or silicon nitride.

The semiconductor package 10 comprises a protective material 7 that covers and protects some, if not all, of the active area. The protective material 7 may protect the active area from environmental hazards such as moisture, contaminants, corrosion, and mechanical shock and stress. Additionally, the protective material may increase the robustness of the package as well as provide a surface for device marking. The protective material 7 may comprise any material known to operate in this manner, including a polyimide (e.g., DUPONT's KAPTON®, or any other tape/film made of polyimide), a covering material 8 (e.g., an epoxy mold, a thermoset resin such as silicones, phenolics, and epoxies, or a thermoplastic).

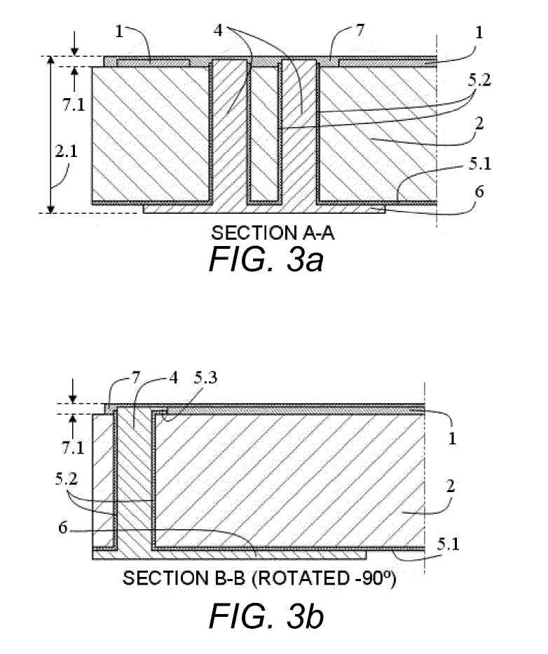

In some embodiments, the semiconductor package 10 comprises a single protective material 7 made of a polyimide, as shown in FIGS. 3a and 4b. In other embodiments, the package 10 can comprise a protective covering made of a covering material 8, such as an epoxy mold, as shown in FIG. 4c. In yet other embodiments, the semiconductor package comprises more than one protective material. The use of multiple protective materials may give the package more protection and make it more robust than a single protective material. The package can comprise any suitable combination of protective materials that allows it to operate as intended. For example, FIG. 2b shows that the active area 1 can be covered by a polyimide layer 7, which, in turn, is covered by a covering material 8.

The protective material(s) on the semiconductor package can be any known thickness. Indeed, the thickness of the protective material(s) (e.g., the polyimide thickness 7.1 in FIG. 3a and the covering material thickness 8.1 in FIG. 2b) may be varied to provide adequate robustness and to achieve a desired total package thickness requirement 2.1. In some embodiments, the thickness of the protective material(s) can range from about 5 to 25 μm.

In some embodiments, an exposed surface of the protective material (e.g., the polyimide 7 or the covering material 8) can have device marking for identification purposes. In such embodiments, the device marking can be put on the protective material in any known manner, including by having the device marking be built-in to the protective material, by printing, or by laser marking.

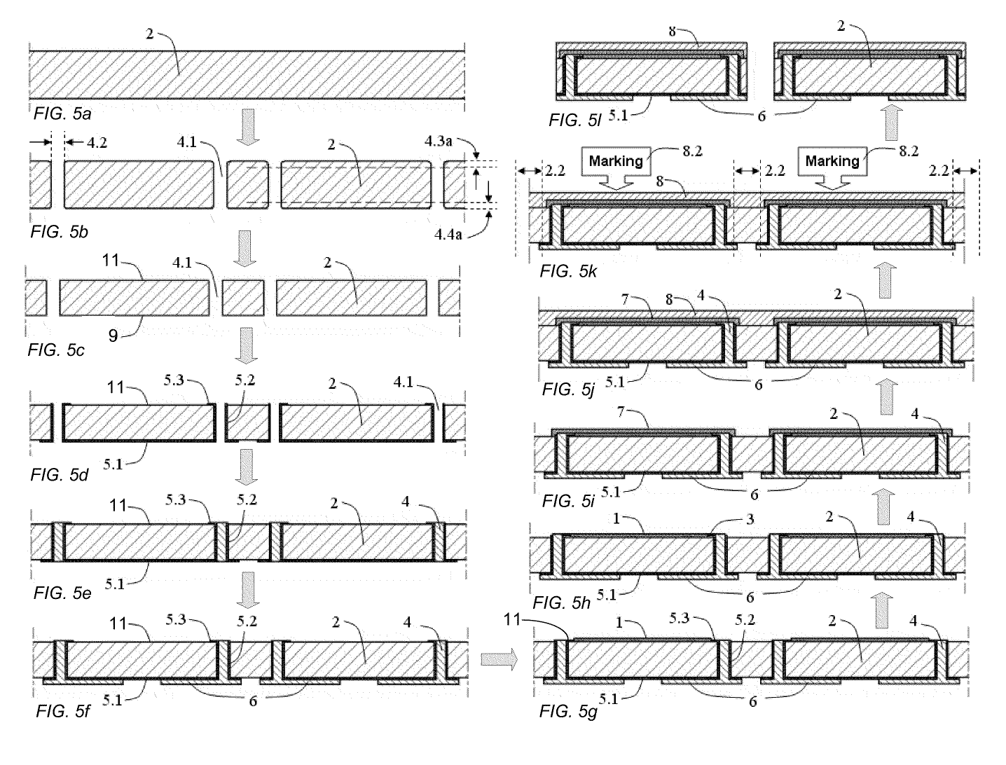

The semiconductor package 10 may be made by any known method that provides the structures described above and illustrated in the Figures. In some embodiments, FIGS. 5a through 5l illustrate one method for producing the package 10. This method begins by providing a substrate 2, such as a silicon wafer. Next, as shown in FIG. 5b, vias (including through-hole vias) 4.1 may be formed in the substrate 2. Such through-hole vias can be formed in any known method, including through chemical etching, laser machining, or a combination thereof.

Next, as depicted in FIG. 5c, the substrate 2 can be thinned by removing a front 4.3a and/or back portion 4.4a. The substrate can be thinned in any known manner, including through chemical etching, plasma etching, grinding or polishing. This thinning process may prepare the front surface 11 of the substrate 2 for the active area and the die back surface 9 for the isolation layer 5.1 and/or the terminal 6.

Then, as shown in FIG. 5d, the isolation material can be applied to the substrate 2 to form isolating layers 5.1, 5.2, and 5.3 on the die back surface 9, the walls of through-hole vias 4.1, and the die front surface 11. The isolation material can be deposited on the substrate in any known manner, including through the use of chemical vapor deposition, or physical deposition.

As shown in FIG. 5e, filled vias 4 can then be formed by filling the isolated through-hole vias 4.1 with a conductive material, such a copper alloy. The conductive material of the filled vias 4 can be deposited in any known method, including through chemical vapor deposition, or physical deposition.

Then, as shown in FIG. 5f, pad terminals 6 may be deposited on the isolating layer 5.1 (or die back surface 9) and may be connected to one or more filled vias 4. The terminals 6 may be deposited on the isolating layer by any known method, including a metal plating process that allows the terminal to suitably adhere to the isolation layer, forming an electrical and mechanical interface to application solder joints, and form an inter-metallic interface to the filled via.

Next, as shown in FIG. 5g, the active area 1 can be formed on the front surface 11. The active area can be formed in any known manner depending on the circuitry, and may include various processes and sub-process to complete particular device circuitry.

Although the traces can be formed during the formation of the active area, FIG. 5h shows some embodiments where the traces 3 are formed separately. In either case, the traces can be deposited in any manner that connects them with the active area and the filled via 4, including through physical deposition, or chemical deposition.

Then, as shown in FIG. 5i, the protective material (e.g., a polyamide 7) can be placed over the active area 1 and the traces 3. In some embodiments, the protective material 7 can be applied through any known deposition process capable of depositing an insulator and/or protective material suitable for this assembly. Additionally, as shown in FIG. 5j, an additional protective material (e.g., covering material 8) can be deposited on the polyimide 7 so as to substantially cover the front surface 11. The covering material 8 can be deposited in any known manner, including any molding process.

Next, as shown in FIG. 5k, an exposed surface of the protective material (e.g., covering material 8) can receive device marking 8.2 through any known manner. Then, as shown in FIG. 5k, the processed substrate can be singulated (as shown by 2.2). Although the singulation can be done in any known manner, in some embodiments it is accomplished by sawing or laser cutting. After singulation, FIG. 5l shows the resulting device can be tested, taped, and reeled, as known in the art.

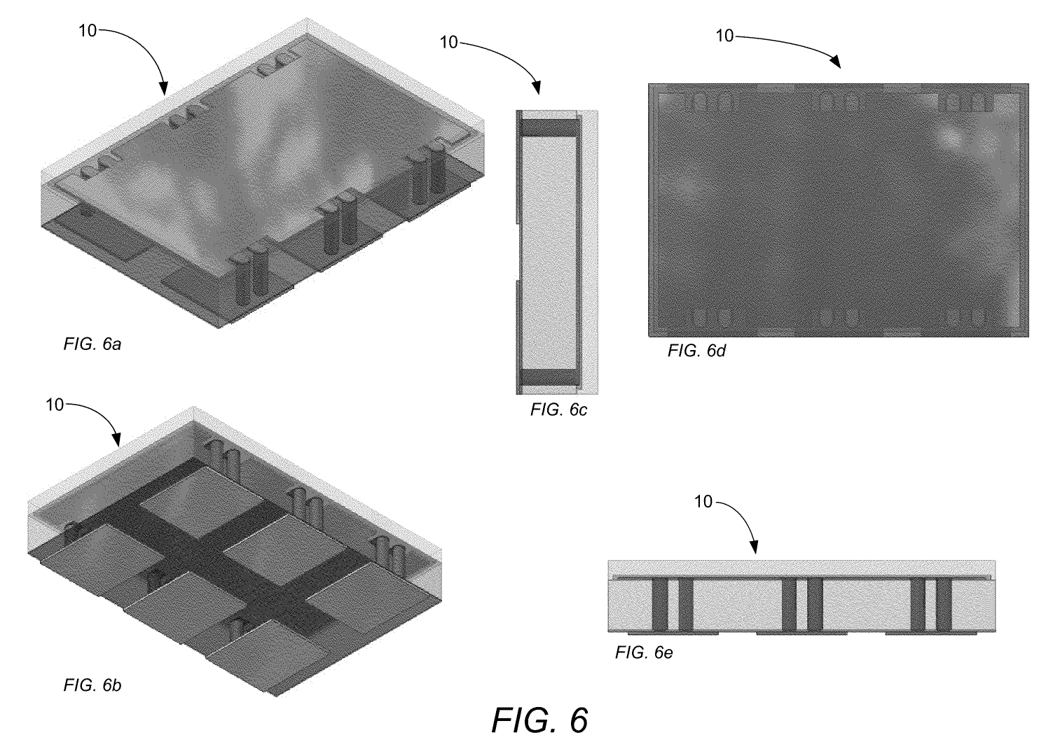

FIGS. 6a through 6e contain several views of the some embodiments of the semiconductor package 10 once it has been manufactured. Although such a package 10 can be used in any suitable design application, in some circumstances, the package is used in a switching device, an analog application, or a driver IC application.

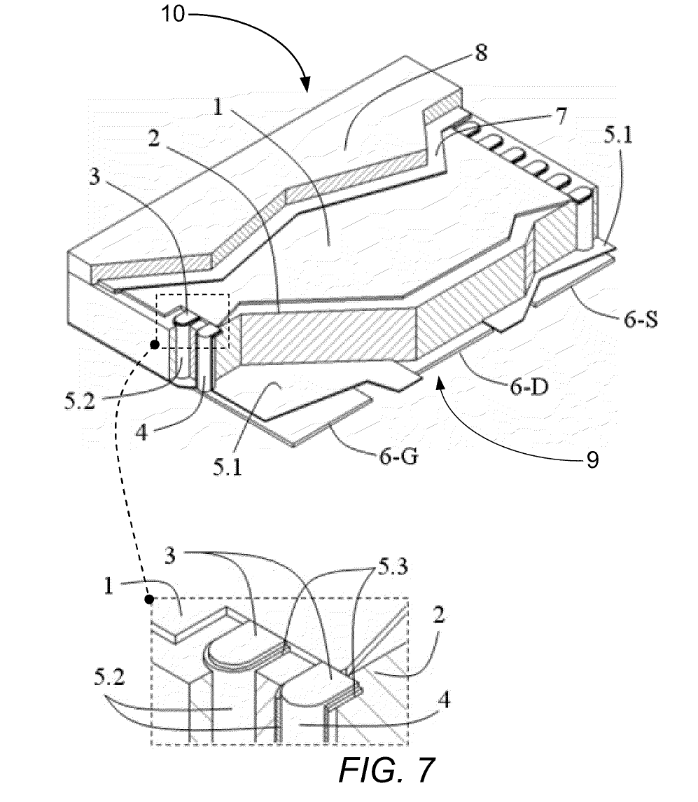

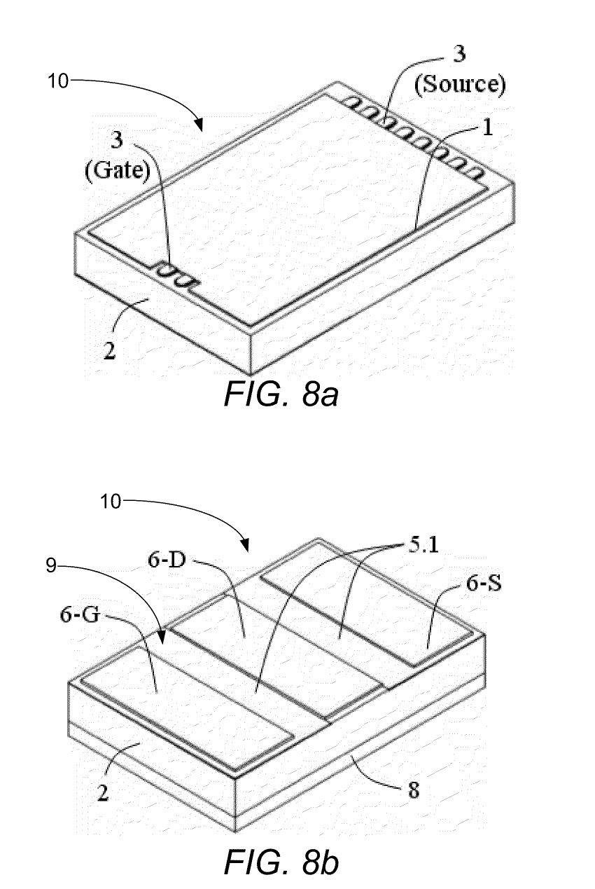

In some embodiments, the active area of the semiconductor package 10 and the terminals are connected in a specific manner. In FIG. 7, the package contains a back surface 9 with terminals that that comprise a gate terminal 6-G, a source terminal 6-S, and a drain terminal 6-D. In FIGS. 7 and 8a, the package 10 contains an active area 1 with a gate region and a source region. The gate and source regions may be electrically connected to corresponding terminals 6-G and 6-S by traces 3 that are connected to filled vias 4.

In these embodiments, the gate and source regions of the active area may each connect to a corresponding terminal with 1, 2, 3, 4, or more filled vias. For example, FIG. 8a shows the gate region can be connected to the gate terminal 6-G by 2 traces 3 connected to vias. In another example, FIG. 7 shows the source region can be connected to the source terminal 6-S by 8 traces 3 and filled vias 4. Nevertheless, depending on the specific electrical requirements, the size (e.g., length, width, and height), and the application of the package, the quantity of metal traces and filled vias can be more or less than what is shown FIGS. 7 and 8a. In other words, while FIGS. 7 and 8a show some embodiments of a typical gate bus layout design, the gate bus layout can be varied to cater to specific output requirements of the semiconductor package.

In these embodiments, the electrical connections between the gate and source regions and the corresponding terminals may be isolated from the substrate in any suitable manner. Indeed, as previously mentioned, the terminals (e.g., 6-G and 6-S) can be isolated from the substrate by an isolation layer 5.1. Similarly, the vias 4 can be isolated from the substrate by isolation layer 5.2. And the traces 3 can be isolated from the substrate by isolation layer 5.3.

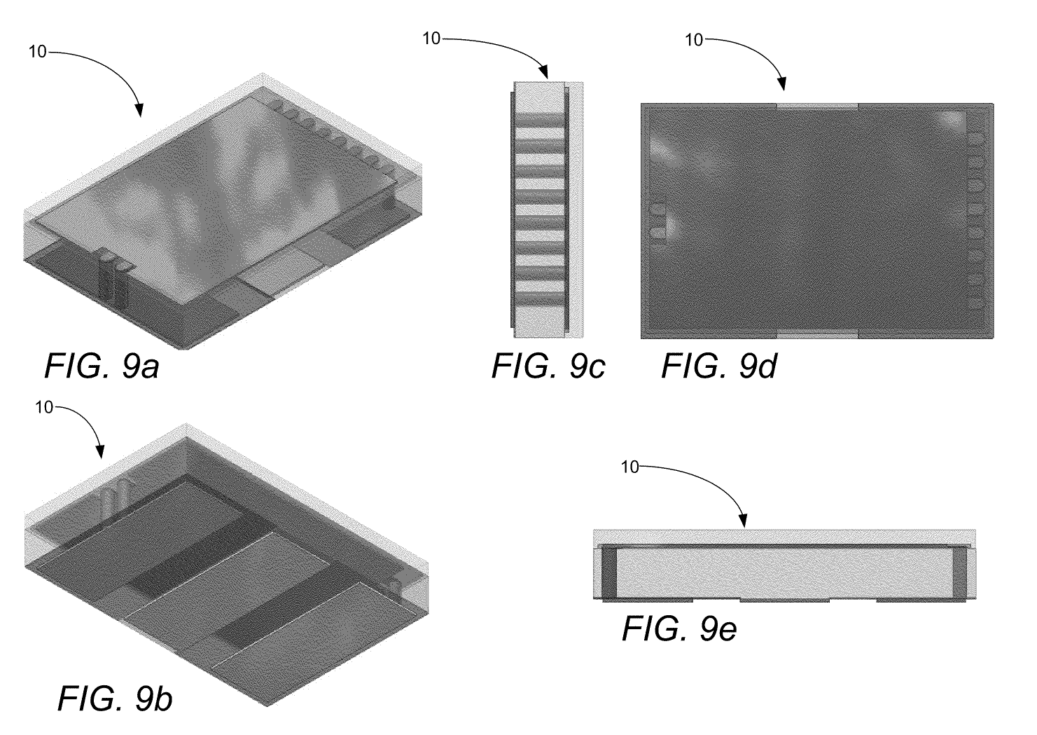

In some embodiments, not all of the terminals are electrically isolated from the substrate. For example, FIGS. 7 and 8b shows the drain terminal 6-D can be electrically connected to the substrate 2, which may function as a drain. In this example, the drain terminal 6-D can be electrically connected to the substrate in any suitable manner. For instance, FIG. 7 shows the drain terminal 6-D can be directly attached to the die back surface 9.

Where the semiconductor package comprises a gate, a source, and a drain terminal on the back surface, the semiconductor package can be made in any suitable manner. For example, the semiconductor package may be made through a process similar to that illustrated in FIGS. 5a-5l, except that the drain terminal can be electrically connected to the substrate. FIGS. 9a through 9e illustrate some embodiments of the package made through such a process.

The semiconductor packages and methods described above have terminals disposed on the substrate back surface. Because the active area can be unencumbered by terminals, it can have more space for circuitry or be made smaller without reducing space for circuitry. Thus, the package can have a smaller footprint than semiconductor packages that have terminals on the active area. Additionally, the active area may not be affected by a change in terminal pad size. And the active area may not be exposed to mechanical stresses between the terminals and the external device.

The semiconductor packages and methods described above also have pad terminals. Pad terminals, as opposed to some other terminal types (e.g., solder balls), may be thinner and smaller. Accordingly, the package may be thinner and smaller by using pad terminals. And because pad terminals may be less likely to deform or become lost during testing and handling, the semiconductor package may be more resilient to damage.

The semiconductor packages can use traces and filled vias to electrically connect the active area to the terminals. Thus, the semiconductor packages provide a better on-resistance (RDSₒₙ) response than some semiconductor packages that have wire or clip bonding.

The semiconductor packages can have a protective material that covers the active area. Such a protective material (e.g., a polyimide and/or a covering material) can increase package rigidity, as well as protect the active area from contaminants and mechanical stresses. And the protective material can provide an area for device marking.

As a result of all of these features, the semiconductor packages can be small, thin, light weight, rigid, and easily produced. Accordingly, the semiconductor packages can have a small foot print and be applied to thin, small, ultra-small, and/or ultra-portable products that require condensed circuitry.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A chip scale semiconductor package, comprising:
a semiconductor substrate containing a front surface that comprises an active area;
a plurality of terminals, wherein each terminal is disposed on the back surface of the substrate;
a filled via extending through the substrate and connecting the active area to a first terminal; and
a trace that electrically connects the active area to the filled via.

2. The package of claim 1, wherein the plurality of terminals comprises a gate terminal, a source terminal, and a drain terminal.

3. The package of claim 2, further comprising a first trace and a first filled via that electrically connect the gate terminal with a gate region of the active area, and a second trace and a second filled via that electrically connect the source terminal with a source region of the active area.

4. The package of claim 3, wherein the gate terminal, the first trace, the first filled via, the source terminal, the second trace, and the second filled via are electrically isolated from the substrate.

5. The package of claim 3, wherein the drain terminal is electrically connected to the substrate.

6. The package of claim 3, wherein the gate terminal is electrically connected to a gate region on the active area, the source terminal is electrically connected to a source region on the active area, and the drain terminal is electrically connected to the substrate.

7. The package of claim 1, wherein at least a portion of the active area is covered by a protective material selected from a polyimide, a covering material, an isolating material, and combinations thereof.

8. The package of claim 1, wherein the plurality of terminals comprise pad terminals.

9. A chip scale semiconductor package, comprising:
a semiconductor substrate containing a front surface that comprises an active area is covered by a protective material selected from a polyimide, a covering material, an isolating material, and combinations thereof;
a plurality of pad terminals, wherein each pad terminal is disposed on the back surface of the substrate;
a filled via extending through the substrate and connecting the active are to a first terminal; and
a trace that electrically connects the active area to the filled via.

10. The package of claim 9, wherein the plurality of terminals comprises a gate terminal, a source terminal, and a drain terminal.

11. The package of claim 10, further comprising a first trace and a first filled via that electrically connect the gate terminal with a gate region of the active area, and a second trace and a second filled via that electrically connect the source terminal with a source region of the active area.

12. The package of claim 11, wherein the gate terminal, the first trace, the first filled via, the source terminal, the second trace, and the second filled via are electrically isolated from the substrate.

13. The package of claim 11, wherein the drain terminal is electrically connected to the substrate.

14. The package of claim 11, wherein the gate terminal is electrically connected to a gate region on the active area, the source terminal is electrically connected to a source region on the active area, and the drain terminal is electrically connected to the substrate.

15. An electronic device containing a chip scale semiconductor package comprising:
a semiconductor substrate containing a front surface that comprises an active area is covered by a protective material selected from a polyimide, a covering material, an isolating material, and combinations thereof;
a plurality of pad terminals, wherein each pad terminal is disposed on the back surface of the substrate;
a filled via extending through the substrate and connecting the active are to a first terminal; and
a trace that electrically connects the active area to the filled via.

16. The device of claim 15, wherein the plurality of terminals comprises a gate terminal, a source terminal, and a drain terminal.

17. The package of claim 16, further comprising a first trace and a first filled via that electrically connect the gate terminal with a gate region of the active area, and a second trace and a second filled via that electrically connect the source terminal with a source region of the active area.

18. The package of claim 17, wherein the gate terminal, the first trace, the first filled via, the source terminal, the second trace, and the second filled via are electrically isolated from the substrate.

19. The package of claim 17, wherein the drain terminal is electrically connected to the substrate.

20. The package of claim 17, wherein the gate terminal is electrically connected to a gate region on the active area, the source terminal is electrically connected to a source region on the active area, and the drain terminal is electrically connected to the substrate.

21. A method for making a chip scale semiconductor package, the method comprising:
providing a semiconductor substrate containing a front surface that comprises an active area;
providing a plurality of terminals, wherein each terminal is disposed on the back surface of the substrate;
providing a filled via extending through the substrate and connecting the active area to a first terminal; and
providing a trace that electrically connects the active area to the filled via.

22. The method of claim 21, wherein the trace, the filled via, and the first terminal are electrically isolated from the substrate.

23. The method of claim 22, wherein the plurality of terminals comprises a gate terminal, a source terminal, and a drain terminal.

24. The method of claim 23, wherein the gate terminal is electrically connected to a gate region on the active area, the source terminal is electrically connected to a source region on the active area, and the drain terminal is electrically connected to the semiconductor substrate.

25. The method of claim 23, further comprising covering at least a portion of the active area with a protective material selected from a polyimide, a covering material, an isolating material, and combinations thereof.
